(19) United States
(12) Patent Application Publication
(10) Pub. No.: US 2025/0181806 A1
(43) Pub. Date: Jun. 5, 2025

(54) LEARNING-BASED PLACEMENT FOR CONGESTION MITIGATION

(71) Applicant: NVIDIA Corp., Santa Clara, CA (US)

(72) Inventors: Anthony Dimitri Armand Agnesina, Atlanta, GA (US); Rongjian Liang, Austin, TX (US); Geraldo Pradipta, Minneapolis, MN (US); Anand Kumar Rajaram, Austin, TX (US); Haoxing Ren, Austin, TX (US)

(73) Assignee: NVIDIA Corp., Santa Clara, CA (US)

(21) Appl. No.: 18/969,053

(22) Filed: Dec. 4, 2024

Related U.S. Application Data
(60) Provisional application No. 63/606,467, filed on Dec. 5, 2023.

(51) Int. Cl. G06F 30/32; G06F 30/27

(52) U.S. Cl. CPC G06F 30/32; G06F 30/27

(57) ABSTRACT

Mechanisms to control cell density in circuit layouts to mitigate placement congestion that learn from post-route target outputs of an Electronic Design Automation system and implement an empirical Bayes mechanisms to adapt the target to a specific component placer's achievable outputs. The disclosed mechanisms solve for component placement on a global scale and obviate the application of incremental congestion estimation and mitigation.

### CROSS-REFERENCE TO RELATED APPLICATIONS

This application claims priority and benefit under 35 U.S.C. 119 (e) to U.S. Application Ser. No. 63/606,467, “Learning-Based Placement for Congestion Mitigation”, filed on Dec. 5, 2023, the contents of which are incorporated herein by reference in their entirety.

### BACKGROUND

Component placement in integrated circuits may have a significant impact on congestion and therefore on the routability of the circuit. This impact arises from ever-increasing cell density, design rules complexity, and the number of macros that are utilized in the circuit. Herein, a “cell” refers to a standard cell, which are the circuit elements to be placed during placement along with larger but much fewer macros blocks. A standard cell is a pre-designed, pre-characterized configuration of logic used as a building block in circuits. These cells typically include basic logic gates such as AND, OR, NOR, NAND, inverters, and flip-flops, for example. Each standard cell is designed to meet specific electrical and physical requirements, and they may be arranged in a manner that facilitates automated design processes.

Standard cells may be characterized for parameters such as power consumption, speed, and area, and there may be different standard cells for different process technologies. By using standard cells, designers can efficiently assemble large and complex digital circuits, ensuring predictable performance and manufacturability.

Cell density is impacted by routability and timing optimizations. Cell density determines placement congestion, i.e., a condition wherein cells and macros are densely packed in local regions of the circuit layout.

The effects of placement congestion include restricting available space for applying optimizations such as gate sizing and buffer insertion, thereby degrading circuit performance.

There is a need for improved mechanisms to efficiently determine and apply cell density constraints (also referred as goals or targets hereafter) for placement of components in the global layout of circuits.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts a conventional component placement process for a circuit.

FIG. 2 depicts aspects of an embodiment of a system to determine settings for a component placement system (“placer”).

FIG. 3 depicts additional aspects of an embodiment of a system to determine settings for a component placer.

FIG. 4 depicts a parallel processing unit in accordance with one embodiment.

FIG. 5 depicts a general processing cluster in accordance with one embodiment.

FIG. 6 depicts a memory partition unit in accordance with one embodiment.

FIG. 7 depicts a streaming multiprocessor in accordance with one embodiment.

FIG. 8 depicts a processing system in accordance with one embodiment.

FIG. 9 depicts an exemplary processing system in accordance with another embodiment.

### DETAILED DESCRIPTION

Electronic Design Automation (EDA) systems are utilized for designing, simulating, and analyzing electronic systems, components, or circuits. These systems provide engineers and companies with efficient means to design (from concept to physical realization) electronic systems such as integrated circuits (ICs), printed circuit boards (PCBs), and other electronic components. Commercial EDA systems may include mechanisms for schematic capture, circuit simulation, PCB layout, and more, to streamline the design process, reduce design errors, and accelerate the time-to-market for electronic products.

Disclosed herein are mechanisms for controlling cell density in circuit layouts to mitigate placement congestion. The disclosed mechanisms learn from an EDA system's post-route optimized outputs (target) and implement an empirical Bayes mechanisms to adapt the target to a specific component placer's solutions.

The disclosed mechanisms may enhance correlation with the long-running heuristics of the EDA system's router and timing-optimizer, while solving placement globally, obviating the application of computationally expensive incremental congestion estimation and mitigation.

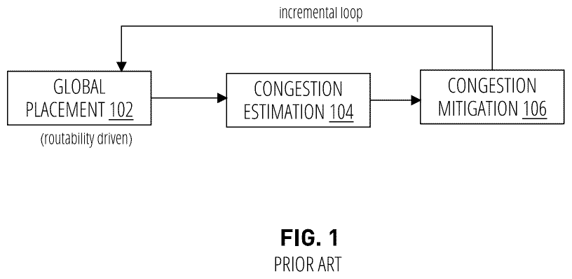

FIG. 1 depicts a conventional component placement process for a circuit. The process comprises an iterative cycle of global placement 102, congestion estimation 104, and congestion mitigation 106.

Routability-driven placement methods often follow a step-wise incremental approach (often implemented within a loop, as depicted in FIG. 1). After each placement increment, congestion is estimated first through various known methods and then mitigated by cell density control.

Incremental methods struggle to adjust the overall placement distribution towards an ideal wirelength and congestion trade-off. This may especially be the case for mixed-size placement where local density changes may unexpectedly disrupt the global layout landscape. The success of these conventional methods relies on the congestion estimation's accuracy, which ultimately depends on a strong correlation with the router's long-running heuristics.

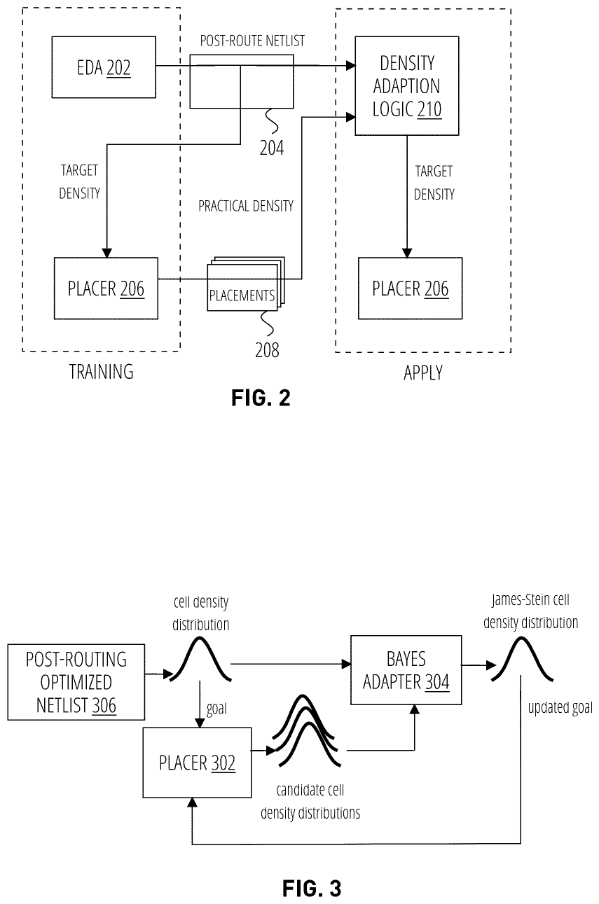

FIG. 2 depicts aspects of an embodiment of a system to determine settings for a component placement system (“placer”). A post-routing circuit netlist generated by an Electronic Design Automation system 202 is processed through cell density distribution determination logic 204 to determine initial cell density targets for a component placement system 206. The component placement system 206 generates candidate component placements 208 that comprise the practical cell densities achievable by the particular component placement system 206. These candidate component placements 208 are processed through density adaption logic 210 to determine next target cell densities for operating the component placement system 206.

FIG. 3 depicts additional aspects of an embodiment of a system to determine settings for a component placer. The system learns the settings to apply to the placer 302 from post-route optimized cell density, specifically from density optimizations performed during the routing stage. Optimizing directly at the placement stage for a desired cell density improves a correlation with the placers assumptions and final results.

At a high level, the disclosed mechanisms derive cell-level density targets from post-route component placements output from an EDA system. Next, an empirical Bayes adapter 304 is operated to adjust these density targets to densities that are practically achievable by a specific placer 302 tool.

A post-routing optimized netlist 306 is transformed into an initial cell density distribution that is provided as a goal to a component placer 302 system. The placer 302 generates a set of candidate cell density distributions during the process of trying to meet the post-route netlist goal. The placer 302 may apply a cell inflation process to meet the density goal. The goal distribution and the candidate distributions may be transformed through a Bayes adapter 304 into a James-Stein cell density distribution which, in the event that a previously applied density distribution goal is not achievable by the placer 302 system, may then be applied to the placer 302 as an updated goal distribution. The process repeats and the placer 302 urges the cell density distribution to converge on an acceptable outcome.

The system urges the placer 302 to converge on a target cell distribution by applying cell density targets that inflate cells during global placement, obviating the congestion estimation and incremental behavior of conventional approaches.

The system generates density targets within a (configured) realistic range of outputs of placer using the empirical Bayes adapter 304.

The cell density may be controlled by the system during a mixed-size global placement to improve placement congestion, without the utilization of congestion estimation. A particular circuit's target (goal) cell density distribution goal may be learned from a prior execution of a commercial EDA system, improving correlation with the EDA system's routing and timing optimization processes.

The empirical Bayes adapter 304 may adjust initial cell density targets derived from post-routing results to achieve improved cell density distributions tailored to a specific placer 302 (e.g., avoiding the generation of cell density distribution targets that are not achievable by a particular placer 302). The Bayes adapter 304 may be specifically configured to account for timing considerations of the circuit (e.g., optimized for circuit timing constraints).

A goal distribution is initially generated from a post-route post-routing optimized netlist 306. The placer 302 generates candidate cell densities based on this goal, and based on these candidates, the Bayes adapter 304 refines the goal for the placer 302.

Utilizing the post-routing optimized netlist 306 cell distribution from a previous execution of a commercial EDA system improves correlation with the EDA system's routing and timing optimization engines.

Component clustering may be scoped at a level that prevents the merging of cells that do not derive from a common hierarchical parent. The clustering may be scoped to Register Transfer Level (RTL) logical groups and timing boundaries. (RTL specifies the flow of data and the logical operations applied to the data through registers and combinational logic.) A top-down traversal of the circuit's RTL may be carried out to identify module boundaries for clustering, stopping when instance counts fall within a predetermined range. Instances lacking hierarchy may be bundled together for clustering.

In one embodiment, a Leiden clustering algorithm may be applied for module decomposition. Clustering may be applied to the clique-expansion graph of the hypergraph netlist, parameterized by Leiden resolution, the RTL module size to break down, and an edge weight, for example. These parameters may be tuned to balance cluster count, the Davies-Bouldin index of physical closeness within a cluster, and the correlation between cluster density (the average of cell densities in a cluster) and timing criticality (the average of cell slacks).

In one embodiment, the clustering mechanism may utilize Tsay-Kuh clique weights incorporating a normalized Levenshtein string distance:

$$d ( \{ u , v \} ∈ ϵ ) = \frac{2}{\vert e \vert ( 1 \cdot Levenshtein ( u , v ) ) )}$$

where the Levenshtein distance emphasizes hierarchical attraction.

Tsay-Kuh clique weights may be applied to assign a numerical value to clusters/cliques based on certain properties or criteria. These weights can be utilized to evaluate or prioritize cliques according to specific objectives, such as maximizing or optimizing around particular parameters.

Levenshtein distance is a metric for measuring the difference between sequences. It quantifies the number of differences between one sequence and another. The possible differences include additions, removals, or substitutions of elements.

The clustering mechanism may accurately identify sets of standard cells in an integrated circuit netlist that consistently co-locate (group together) across different placement configurations.

An average cell density and timing criticality of each cluster may be determined to uncover correlation (PDT) between lower density and higher timing criticality. This correlation may be particularly important in timing-critical clusters, the cells of which may be configured for low density using the empirical Bayes adapter 304.

During the process of circuit synthesis, changes to cell density may occur between the global placement stage and post-route optimization, taking into account only those cells present in both stages, adjusted to post-synthesis sizes. The density shift results from placement adjustments rather than adding new cells or gate resizing. The rise in average cell density, driven by the timing-driven placement that pulls cells together, indicates that post-route cell density-reflecting later-stage timing and congestion optimizations-comprises information useful to optimization.

An EDA system may be operated to generate post-route optimizations on a placed netlist to establish an initial target cell density for the placer 302.

To determine cell density, the floorplan circuit design may be discretized into a two-dimensional (2D) grid of bins B. The floorplan of a circuit refers to the layout design that outlines the placement of various functional blocks and the interconnections between them. The floorplan may for example map out areas for logic blocks, data paths, memory, input/output (I/O) pads, and power distribution networks. Considerations of a floorplan design may for example include minimizing signal delay, optimizing power distribution, and ensuring efficient heat dissipation. The floor planning stage may precede and informs further detailed physical design processes such as routing and wire planning.

The floor plan for a circuit may be organized into bins (regions) of a grid. For any bin b∈B and cell i∈V, let OA (i, b) be their overlapping area in the floorplan, and Ab and ai represent their respective circuit areas. The bin density p_{b} and cell density pᵢ may be determined as:

$${p}_{b} = {\sum }_{i ∈ V} \frac{OA ( i , b )}{{A}_{b}}$$

$$and$$

$${p}_{i} = {\sum }_{b ∈ B} {p}_{b} \frac{OA ( i , b )}{{a}_{i}}$$

In one embodiment, the cell density may be determined using square bins of size s×s (e.g., 10×10) each with a standard cell row height. Density targets of the cells in the placed netlist may be determined from the post-route optimized output of the EDA system as follows:
Buffers are removed;
Cells in both placed and post-route netlists are placed in their post-route positions (including macros) and sized to their post-synthesis size;
The remaining standard cells that do not match are set to “zero” size-in practice, for example, these remaining standard cells may be set to site width and row height, where a site is the smallest unit of placement for a cell available to the placer 302.

Setting the remaining standard cells to zero size provisions space for their replacement with other cells found in the post-route netlist, effectively decreasing the target density of matching cells in the placed netlist. This accounts for space needed by later timing-optimization steps that insert buffers and upsize and pull together timing-critical cells. Timing-driven placers may also pad cells on timing-critical paths. The non-matching cells may also be set to zero size during global placement and for density map comparison. They may be reverted to actual size for legalization (e.g., checking for design rule constraint compliance) and more fine-grained placement.

The disclosed mechanisms may apply cell inflation as guidance to the placer to achieve target cell densities. However, some placers may struggle to achieve target post-route densities while also optimizing for other target objectives such as certain maximum or average wirelengths in the routing. The disclosed mechanisms may therefore adapt target densities for a specific placer by learning from its placement solutions rather than imposing a possibly unrealistic density distribution target on the placer.

In one embodiment, the achievable densities for the placer are derived using a top 50 Pareto point global placements (from said placer) and their achieved cell densities, using inflation with the initial density goat targets. A Pareto point, in the context of multi-objective optimization, refers to a solution for which it is impractical or impossible to improve one objective without causing a degradation in at least one other objective. Pareto points may be utilized in decision-making processes where balance or tradeoffs among competing goals occur.

The focus on Pareto points may help ensure diversity among and high placement quality in the various global placements. The density distributions from the placer may be biased using inflation to improve the learning function.

Let zᵢₖ denote the density of cell i from the k-th Pareto placement (k=1, 2, . . . , 50). For each cell, the cell density across placements may closely follow a Gaussian distribution with small variance. Assume each cell density has a true expectation μᵢ to be estimated from the placer density zᵢ and the placer's placements prior. The prior encodes a preconceived “belief” that the target density will resemble the placer's output densities. Assume normally distributed cell densities from the placer:

$${z}_{i} - ℕ ( {μ}_{i} , {σ}_{0}^{2} ) ( i = 1 , 2 , … , N )$$

where N is the number of cells, and taking variance σ₀² as known (e.g., as var{zᵢ). Without any prior knowledge of how differently the unknown parameters μᵢ might arrange themselves, the estimators are \hat{μ}ᵢ=zᵢ for i=1, 2, . . . N, these being maximum likelihood estimates.

The James-Stein Bayes Estimator/Adapter may be applied in the process at this stage. The James-Stein estimator is a statistical technique used for estimating the mean of a multivariate normal distribution. It improves upon a classical sample mean estimator, particularly in high-dimensional settings, by incorporating concepts from Bayesian estimation. Assume a vector X=(X₁, X₂, . . . , Xₚ) where each Xᵢ is an independent and identically distributed variable with a normal distribution Xᵢ− [symbol] (μᵢ, σ₀²) (i=1, 2, . . . , N). The goal of the Bayes adapter/estimator is to estimate the vector of means μ=(μ₁, μ₂, . . . , μₚ).

Applying the sample mean \hat{μ}=X as the estimator results in a maximum likelihood estimator that is unbiased. However, when p≥3, the sample mean estimator is not the best (in terms of the mean squared error risk), and can be improved upon by shrinking the estimates toward a central point. The James-Stein estimator shrinks the sample means toward zero (or a central value) using the formula:

$${\hat{μ}}_{JS} = ( 1 - \frac{( p - 2 ) {σ}^{2}}{{‖ X ‖}^{2}} ) X$$

Here, ∥X∥² is the sum of squares of the sample estimates, and the shrinkage factor

$$( 1 - \frac{( p - 2 ) {σ}^{2}}{{‖ X ‖}^{2}} )$$

effectively reduces the variance of the estimates without introducing significant bias.

The James-Stein estimator may be understood to be a Bayesian or empirical Bayes estimator when considering a prior distribution that shrinks towards the origin. This shrinkage reflects a form of regularization, stabilizing estimates, especially when p is large relative to the sample size. The James-Stein estimator is particularly useful in scenarios involving multiple parameters because it balances bias and variance more effectively than the traditional sample mean estimator, resulting in overall improved performance.

The James-Stein estimator embodies a “middle-ground” between the prior and target densities, by shifting the target toward the placer's densities. If the shrinking factor were equal to 1, then the James-Stein estimate for a given cell the density from the placer. By setting the shrinking factor to be less than 1, when the target density of a cell is much higher than what the placer can achieve, it is reduced, and vice versa. This shifts density targets that are unachievable by a given placer to more achievable density targets. For p≥3, the James-Stein estimator is proven to improve over the basic maximum likelihood estimation (MLE) in terms of expected total squared error (the “risk” R).

Even in scenarios in which the signal-to-noise ratio is low (A«σ2 0), the James-Stein risk may converge quickly towards optimality as the number of cells N increases. The James-Stein estimator pools together density information from potentially all cells. Target densities derived from a James-Stein based Bayes adapter 304 may enhance component placement congestion and improve routing wirelength outcomes when applied to inflate cells inside the placer 302.

The potential for degradation in circuit timing characteristics from application of the James-Stein density targets in the placer may be addressed by targeting the inflation factors in timing-critical areas of the circuit.

The James-Stein mechanism may concentrate attention on the total squared error loss function

$$\sum {( - {μ}_{i} )}^{2} ,$$

without accounting for effects on individual cells. Low-density, timing-critical cells may incur timing issues if they are reduced too extensively in size toward the mean.

The disclosed mechanisms may utilize a mechanism that incorporates a majority of the group density improvements while protecting individual cases of timing-critical cells with a more targeted inflation. With these mechanisms the James-Stein densities may be constrained to not deviate more that an amount Dᵢσ₀ from \hat{μ}_{i,MLE}=zᵢ and Dᵢ is set according to the timing-criticality of the cell:

$$\begin{matrix}{\hat{μ}}_{i , JS / D} = max ( {\hat{μ}}_{i , JS} , {\hat{μ}}_{i , MLE} - {D}_{i} {σ}_{0} ) for {z}_{i} > {\hat{μ}}_{i , p} \\ {\hat{μ}}_{i , JS / D} = min ( {\hat{μ}}_{i , JS} , {\hat{μ}}_{i , MLE} + {D}_{i} {σ}_{0} ) for {z}_{i} \leq {\hat{μ}}_{i , p}\end{matrix}$$

In one embodiment, Dᵢ may be set to be a 10-quantile post-route slack value of each cell. For cells having a highest timing-criticality (e.g., at or exceeding a configured threshold), Dᵢ may be set to a lowest value of one (1), which constrains \hat{μ}_{i,JS/D} to never deviate more than σ₀ from zᵢ. This tightens the density target for cells meeting timing-critical criteria.

Cell inflation may be applied to enforce within the placer 302 a cell density target established by the Bayes adapter 304.

Within a circuit, congestion is often non-uniform, particularly in situations in which the circuit includes routing obstacles such as macros. Uniformly-applied cell inflation may result in congestion situations in the circuit, and a non-uniform cell placement density may alleviate this congestion in some cases.

Some placer systems may utilize an electrostatics Poisson equation to spread the cells:

$${∇}^{2} φ = - ρ = - ∇ ε$$

where φ is the electric potential, ρ the cell density, and E the electric field (=cell spreading force). This mechanisms may yield a null field when the floorplan density is uniform, i.e., ρ=dt, where dt is a user-defined global target density that dictates an amount of fillers. The disclosed approaches may modify this mechanism to achieve non-uniform density in a circuit.

A cell's size may be increased using an inflation factor rᵢ≥1 to achieve a lower local density than the overall target density goal. Standard cells may be inflated only in the x-direction (to comply with layout constraints for standard cells) while updating pin offsets, resulting in an inflated cell having an inflated width w′ᵢ (y-direction extent) of rᵢwᵢ, where wᵢ is the original un-inflated cell width.

A uniform density leads to ρ_{b}≈dₜ, ∀b∈B. Assuming that each standard cell belongs to one bin only and ignoring bins covered by macros, where the target density of cell i is denoted by tᵢ, the effective bin density without inflation may be expressed as:

$${\tilde{p}}_{b} = {\sum }_{i ⊂ b} \frac{{a}_{i}}{{A}_{b}} .$$

In a dense placement region devoid of fillers or macros, where cells are tightly packed but should be spread, meeting targets tᵢ requires satisfying:

$$\frac{1}{{max \{ {r}_{i} \}}_{i ⊂ b}} \leq {t}_{i} \leq \frac{1}{{min \{ {r}_{i} \}}_{i ⊂ b}} ; where ∀ i ⊂ b$$

This leads to an inflation factor for each cell i:

$${r}_{i} = \frac{1}{{t}_{i}}$$

The target matching error using the above inflation factor may be expressed as:

$${min \{ {t}_{i} \}}_{i ⊂ b} \leq {\tilde{p}}_{b} \leq {max \{ {t}_{i} \}}_{i ⊂ b}$$

indicating that cells in the same bin should be assigned similar density targets.

The placer 302 may be configured to optimize wirelength concurrently with cell density as follows. The per-bin target range may be defined as:

$${max \{ {t}_{i} \}}_{i ⊂ b} - {min \{ {t}_{i} \}}_{i ⊂ b}$$

Wide target ranges may lead to undesirable outcomes: cells with high density targets may reach lower density when they should be packed to reduce wirelength, whereas low-density cells may reach higher density when they should be spread out to improve congestion and leave space for timing optimization. A total range error for later evaluation may be defined as:

$$err = {\sum }_{b ∈ B} ( {max \{ {t}_{i} \}}_{i ⊂ b} - {min \{ {t}_{i} \}}_{i ⊂ b} ) for b \vert Avg \{ {t}_{i} \} i ⊂ b \leq {\tilde{p}}_{b}$$

which applied to only the bins violating the average target cell density.

Component placements yielding improved congestion and timing may be identified as follows. The placer 302 may be configured with an additional objective to identify component placements that closely align with the target cell density distribution. For multi-objective Bayesian optimization, the cell density distribution achieved by a placement solution D_{P} may be compared with the target distribution D_{T} (=histogram of z, \hat{μ}_{i,JS}, or \hat{μ}_{i,JS/D}). A symmetric Hellinger distance may be computed on a number (e.g., 100) of histograms of the cell densities

$$H ( {D}_{p} , {D}_{T} ) = \frac{1}{\sqrt{2}} {‖ \sqrt{{D}_{p}} - \sqrt{{D}_{T}} ‖}_{2} ∈ [ 0 , 1 ]$$

A goal may be configured to minimize this distance and utilized to guide the search for placement solution candidates

In one embodiment, the target cell densities may be shifted by an additional tuning parameter in a narrow range (e.g., [−0.2, 0.2]). This parameter may serve as a minimization objective of the placer 302, essentially replacing the uniform density target dₜ, which may be fixed to 1 for cell inflation. The shifted target distributions may be utilized when computing the Hellinger distance.

The mechanisms disclosed herein may be implemented in and/or by computing devices utilizing one or more graphic processing unit (GPU) and/or general purpose data processor (e.g., a ‘central processing unit’ or CPU). An exemplary embodiment comprises machine-readable instructions stored in a machine memory and one or more graphics processing unit and/or central processing unit that the instructions configure to implement the disclosed mechanisms. Exemplary architectures will now be described that may be configured to implement the mechanisms disclosed herein.

The following description may use certain acronyms and abbreviations as follows:
“DPC” refers to a “data processing cluster”;
“GPC” refers to a “general processing cluster”;
“I/O” refers to a “input/output”;
“L1 cache” refers to “level one cache”;
“L2 cache” refers to “level two cache”;
“LSU” refers to a “load/store unit”;
“MMU” refers to a “memory management unit”;
“MPC” refers to an “M-pipe controller”;
“PPU” refers to a “parallel processing unit”;
“PROP” refers to a “pre-raster operations unit”;
“ROP” refers to a “raster operations”;
“SFU” refers to a “special function unit”;
“SM” refers to a “streaming multiprocessor”;
“Viewport SCC” refers to “viewport scale, cull, and clip”;
“WDX” refers to a “work distribution crossbar”; and
“XBar” refers to a “crossbar”.

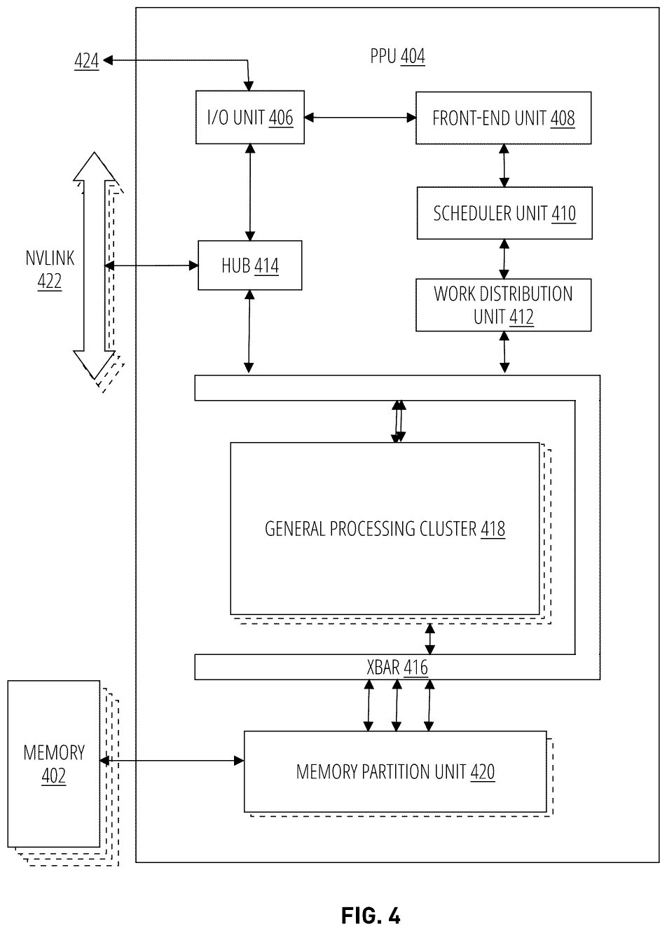

FIG. 4 depicts a parallel processing unit 404, in accordance with an embodiment. In an embodiment, the parallel processing unit 404 is a multi-threaded processor that is implemented on one or more integrated circuit devices. The parallel processing unit 404 is a latency hiding architecture designed to process many threads in parallel. A thread (e.g., a thread of execution) is an instantiation of a set of instructions configured to be executed by the parallel processing unit 404. In an embodiment, the parallel processing unit 404 is a graphics processing unit (GPU) configured to implement a graphics rendering pipeline for processing three-dimensional (3D) graphics data in order to generate two-dimensional (2D) image data for display on a display device such as a liquid crystal display (LCD) device. In other embodiments, the parallel processing unit 404 may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

One or more parallel processing unit 404 modules may be configured to accelerate thousands of High Performance Computing (HPC), data center, and machine learning applications. The parallel processing unit 404 may be configured to accelerate numerous deep learning systems and applications including autonomous vehicle platforms, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

As shown in FIG. 4, the parallel processing unit 404 includes an I/O unit 406, a front-end unit 408, a scheduler unit 410, a work distribution unit 412, a hub 414, a crossbar 416, one or more general processing cluster 418 modules, and one or more memory partition unit 420 modules. The parallel processing unit 404 may be connected to a host processor or other parallel processing unit 404 modules via one or more high-speed NVLink 422 interconnects. The parallel processing unit 404 may be connected to a host processor or other peripheral devices via an interconnect 424. The parallel processing unit 404 may also be connected to a local memory comprising a number of memory 402 devices. In an embodiment, the local memory may comprise a number of dynamic random access memory (DRAM) devices. The DRAM devices may be configured as a high-bandwidth memory (HBM) subsystem, with multiple DRAM dies stacked within each device. The memory 402 may comprise logic to configure the parallel processing unit 404 to carry out aspects of the techniques disclosed herein.

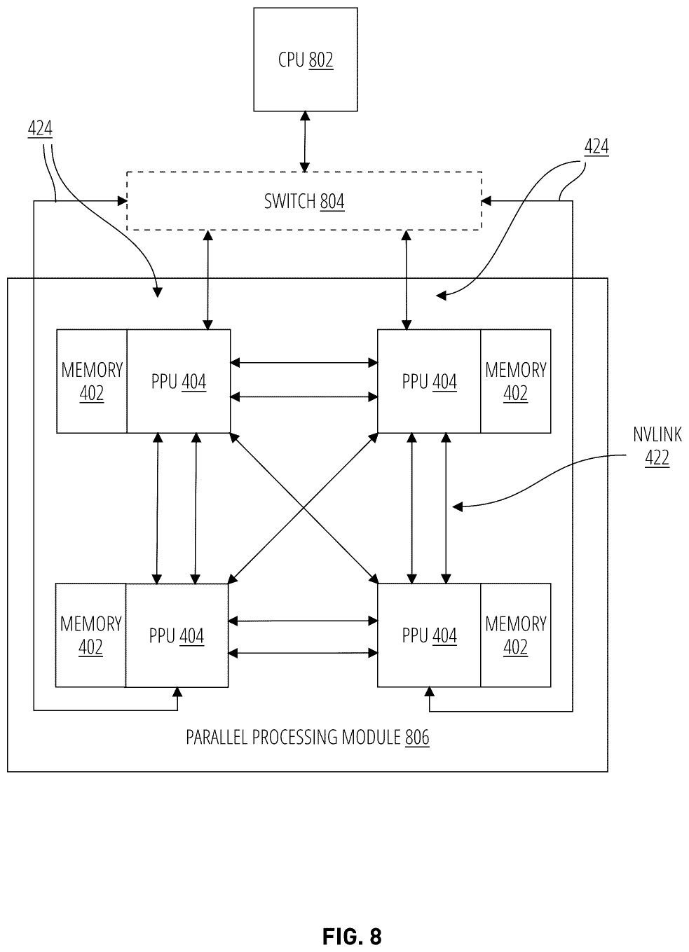

The NVLink 422 interconnect enables systems to scale and include one or more parallel processing unit 404 modules combined with one or more CPUs, supports cache coherence between the parallel processing unit 404 modules and CPUs, and CPU mastering. Data and/or commands may be transmitted by the NVLink 422 through the hub 414 to/from other units of the parallel processing unit 404 such as one or more copy engines, a video encoder, a video decoder, a power management unit, etc. (not explicitly shown). The NVLink 422 is described in more detail in conjunction with FIG. 8.

The I/O unit 406 is configured to transmit and receive communications (e.g., commands, data, etc.) from a host processor (not shown) over the interconnect 424. The I/O unit 406 may communicate with the host processor directly via the interconnect 424 or through one or more intermediate devices such as a memory bridge. In an embodiment, the I/O unit 406 may communicate with one or more other processors, such as one or more parallel processing unit 404 modules via the interconnect 424. In an embodiment, the I/O unit 406 implements a Peripheral Component Interconnect Express (PCIe) interface for communications over a PCIe bus and the interconnect 424 is a PCIe bus. In alternative embodiments, the I/O unit 406 may implement other types of well-known interfaces for communicating with external devices.

The I/O unit 406 decodes packets received via the interconnect 424. In an embodiment, the packets represent commands configured to cause the parallel processing unit 404 to perform various operations. The I/O unit 406 transmits the decoded commands to various other units of the parallel processing unit 404 as the commands may specify. For example, some commands may be transmitted to the front-end unit 408. Other commands may be transmitted to the hub 414 or other units of the parallel processing unit 404 such as one or more copy engines, a video encoder, a video decoder, a power management unit, etc. (not explicitly shown). In other words, the I/O unit 406 is configured to route communications between and among the various logical units of the parallel processing unit 404.

In an embodiment, a program executed by the host processor encodes a command stream in a buffer that provides workloads to the parallel processing unit 404 for processing. A workload may comprise several instructions and data to be processed by those instructions. The buffer is a region in a memory that is accessible (e.g., read/write) by both the host processor and the parallel processing unit 404. For example, the I/O unit 406 may be configured to access the buffer in a system memory connected to the interconnect 424 via memory requests transmitted over the interconnect 424. In an embodiment, the host processor writes the command stream to the buffer and then transmits a pointer to the start of the command stream to the parallel processing unit 404. The front-end unit 408 receives pointers to one or more command streams. The front-end unit 408 manages the one or more streams, reading commands from the streams and forwarding commands to the various units of the parallel processing unit 404.

The front-end unit 408 is coupled to a scheduler unit 410 that configures the various general processing cluster 418 modules to process tasks defined by the one or more streams. The scheduler unit 410 is configured to track state information related to the various tasks managed by the scheduler unit 410. The state may indicate which general processing cluster 418 a task is assigned to, whether the task is active or inactive, a priority level associated with the task, and so forth. The scheduler unit 410 manages the execution of a plurality of tasks on the one or more general processing cluster 418 modules.

The scheduler unit 410 is coupled to a work distribution unit 412 that is configured to dispatch tasks for execution on the general processing cluster 418 modules. The work distribution unit 412 may track a number of scheduled tasks received from the scheduler unit 410. In an embodiment, the work distribution unit 412 manages a pending task pool and an active task pool for each of the general processing cluster 418 modules. The pending task pool may comprise a number of slots (e.g., 32 slots) that contain tasks assigned to be processed by a particular general processing cluster 418. The active task pool may comprise a number of slots (e.g., 4 slots) for tasks that are actively being processed by the general processing cluster 418 modules. As a general processing cluster 418 finishes the execution of a task, that task is evicted from the active task pool for the general processing cluster 418 and one of the other tasks from the pending task pool is selected and scheduled for execution on the general processing cluster 418. If an active task has been idle on the general processing cluster 418, such as while waiting for a data dependency to be resolved, then the active task may be evicted from the general processing cluster 418 and returned to the pending task pool while another task in the pending task pool is selected and scheduled for execution on the general processing cluster 418.

The work distribution unit 412 communicates with the one or more general processing cluster 418 modules via crossbar 416. The crossbar 416 is an interconnect network that couples many of the units of the parallel processing unit 404 to other units of the parallel processing unit 404. For example, the crossbar 416 may be configured to couple the work distribution unit 412 to a particular general processing cluster 418. Although not shown explicitly, one or more other units of the parallel processing unit 404 may also be connected to the crossbar 416 via the hub 414.

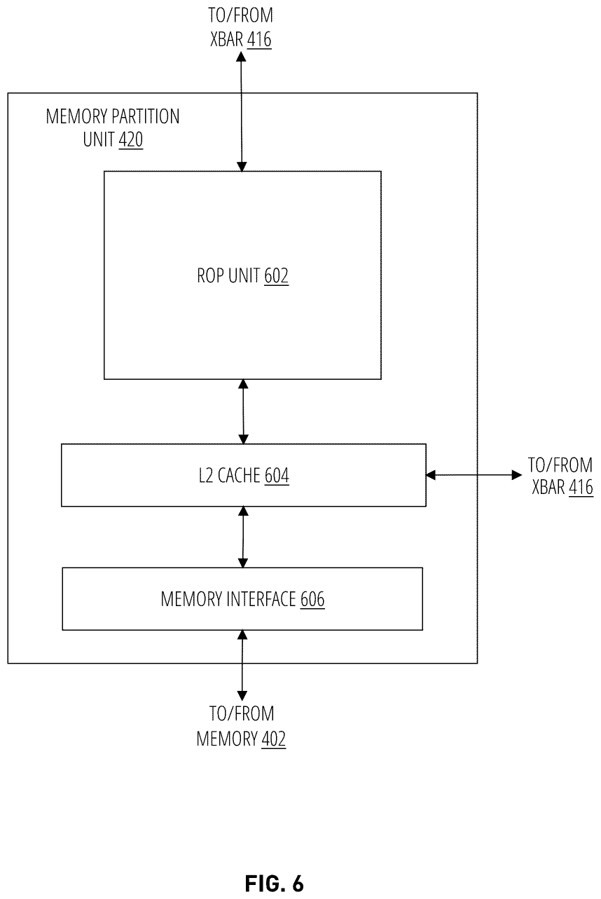

The tasks are managed by the scheduler unit 410 and dispatched to a general processing cluster 418 by the work distribution unit 412. The general processing cluster 418 is configured to process the task and generate results. The results may be consumed by other tasks within the general processing cluster 418, routed to a different general processing cluster 418 via the crossbar 416, or stored in the memory 402. The results can be written to the memory 402 via the memory partition unit 420 modules, which implement a memory interface for reading and writing data to/from the memory 402. The results can be transmitted to another parallel processing unit 404 or CPU via the NVLink 422. In an embodiment, the parallel processing unit 404 includes a number U of memory partition unit 420 modules that is equal to the number of separate and distinct memory 402 devices coupled to the parallel processing unit 404. A memory partition unit 420 will be described in more detail below in conjunction with FIG. 6.

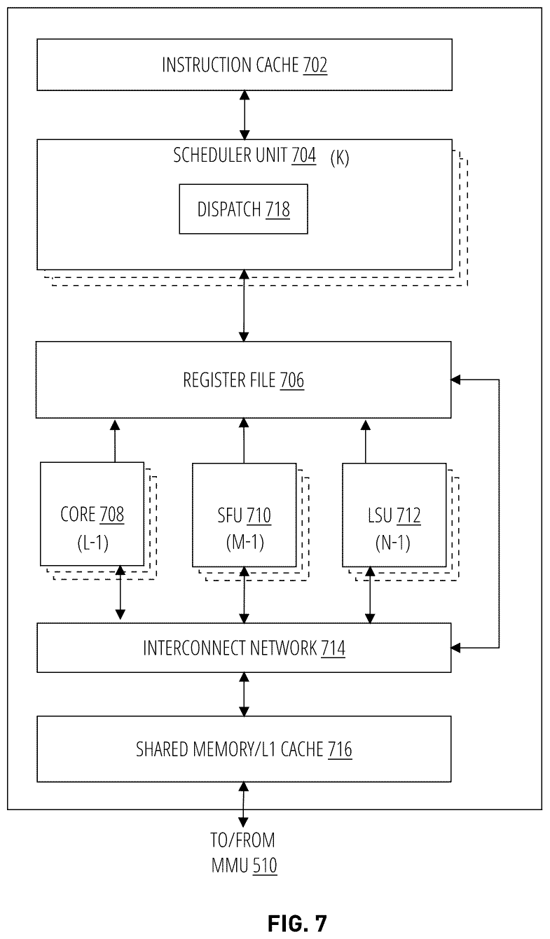

In an embodiment, a host processor executes a driver kernel that implements an application programming interface (API) that enables one or more applications executing on the host processor to schedule operations for execution on the parallel processing unit 404. In an embodiment, multiple compute applications are simultaneously executed by the parallel processing unit 404 and the parallel processing unit 404 provides isolation, quality of service (QoS), and independent address spaces for the multiple compute applications. An application may generate instructions (e.g., API calls) that cause the driver kernel to generate one or more tasks for execution by the parallel processing unit 404. The driver kernel outputs tasks to one or more streams being processed by the parallel processing unit 404. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory. Threads and cooperating threads are described in more detail in conjunction with FIG. 7.

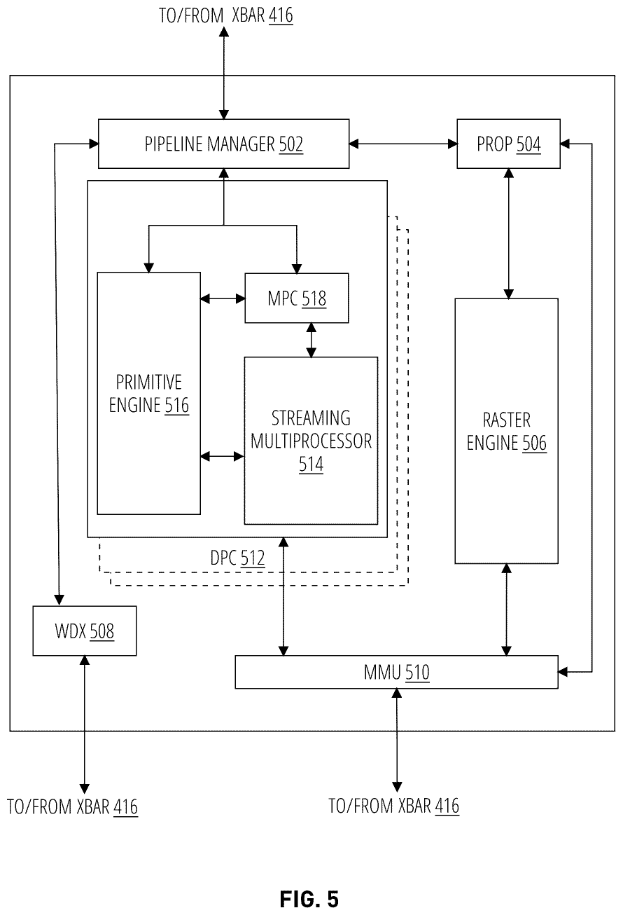

FIG. 5 depicts a general processing cluster 418 of the parallel processing unit 404 of FIG. 4, in accordance with an embodiment. As shown in FIG. 5, each general processing cluster 418 includes a number of hardware units for processing tasks. In an embodiment, each general processing cluster 418 includes a pipeline manager 502, a pre-raster operations unit 504, a raster engine 506, a work distribution crossbar 508, a memory management unit 510, and one or more data processing cluster 512. It will be appreciated that the general processing cluster 418 of FIG. 5 may include other hardware units in lieu of or in addition to the units shown in FIG. 5.

In an embodiment, the operation of the general processing cluster 418 is controlled by the pipeline manager 502. The pipeline manager 502 manages the configuration of the one or more data processing cluster 512 modules for processing tasks allocated to the general processing cluster 418. In an embodiment, the pipeline manager 502 may configure at least one of the one or more data processing cluster 512 modules to implement at least a portion of a graphics rendering pipeline. For example, a data processing cluster 512 may be configured to execute a vertex shader program on the programmable streaming multiprocessor 514. The pipeline manager 502 may also be configured to route packets received from the work distribution unit 412 to the appropriate logical units within the general processing cluster 418. For example, some packets may be routed to fixed function hardware units in the pre-raster operations unit 504 and/or raster engine 506 while other packets may be routed to the data processing cluster 512 modules for processing by the primitive engine 516 or the streaming multiprocessor 514. In an embodiment, the pipeline manager 502 may configure at least one of the one or more data processing cluster 512 modules to implement a neural network model and/or a computing pipeline.

The pre-raster operations unit 504 is configured to route data generated by the raster engine 506 and the data processing cluster 512 modules to a Raster Operations (ROP) unit, described in more detail in conjunction with FIG. 6. The pre-raster operations unit 504 may also be configured to perform optimizations for color blending, organize pixel data, perform address translations, and the like.

The raster engine 506 includes a number of fixed function hardware units configured to perform various raster operations. In an embodiment, the raster engine 506 includes a setup engine, a coarse raster engine, a culling engine, a clipping engine, a fine raster engine, and a tile coalescing engine. The setup engine receives transformed vertices and generates plane equations associated with the geometric primitive defined by the vertices. The plane equations are transmitted to the coarse raster engine to generate coverage information (e.g., an x, y coverage mask for a tile) for the primitive. The output of the coarse raster engine is transmitted to the culling engine where fragments associated with the primitive that fail a z-test are culled, and transmitted to a clipping engine where fragments lying outside a viewing frustum are clipped. Those fragments that survive clipping and culling may be passed to the fine raster engine to generate attributes for the pixel fragments based on the plane equations generated by the setup engine. The output of the raster engine 506 comprises fragments to be processed, for example, by a fragment shader implemented within a data processing cluster 512.

Each data processing cluster 512 included in the general processing cluster 418 includes an M-pipe controller 518, a primitive engine 516, and one or more streaming multiprocessor 514 modules. The M-pipe controller 518 controls the operation of the data processing cluster 512, routing packets received from the pipeline manager 502 to the appropriate units in the data processing cluster 512. For example, packets associated with a vertex may be routed to the primitive engine 516, which is configured to fetch vertex attributes associated with the vertex from the memory 402. In contrast, packets associated with a shader program may be transmitted to the streaming multiprocessor 514.

The streaming multiprocessor 514 comprises a programmable streaming processor that is configured to process tasks represented by a number of threads. Each streaming multiprocessor 514 is multi-threaded and configured to execute a plurality of threads (e.g., 32 threads) from a particular group of threads concurrently. In an embodiment, the streaming multiprocessor 514 implements a Single-Instruction, Multiple-Data (SIMD) architecture where each thread in a group of threads (e.g., a warp) is configured to process a different set of data based on the same set of instructions. All threads in the group of threads execute the same instructions. In another embodiment, the streaming multiprocessor 514 implements a Single-Instruction, Multiple Thread (SIMT) architecture where each thread in a group of threads is configured to process a different set of data based on the same set of instructions, but where individual threads in the group of threads are allowed to diverge during execution. In an embodiment, a program counter, call stack, and execution state is maintained for each warp, enabling concurrency between warps and serial execution within warps when threads within the warp diverge. In another embodiment, a program counter, call stack, and execution state is maintained for each individual thread, enabling equal concurrency between all threads, within and between warps. When execution state is maintained for each individual thread, threads executing the same instructions may be converged and executed in parallel for maximum efficiency. The streaming multiprocessor 514 will be described in more detail below in conjunction with FIG. 7.

The memory management unit 510 provides an interface between the general processing cluster 418 and the memory partition unit 420. The memory management unit 510 may provide translation of virtual addresses into physical addresses, memory protection, and arbitration of memory requests. In an embodiment, the memory management unit 510 provides one or more translation lookaside buffers (TLBs) for performing translation of virtual addresses into physical addresses in the memory 402.

FIG. 6 depicts a memory partition unit 420 of the parallel processing unit 404 of FIG. 4, in accordance with an embodiment. As shown in FIG. 6, the memory partition unit 420 includes a raster operations unit 602, a level two cache 604, and a memory interface 606. The memory interface 606 is coupled to the memory 402. Memory interface 606 may implement 32, 64, 128, 1024-bit data buses, or the like, for high-speed data transfer. In an embodiment, the parallel processing unit 404 incorporates U memory interface 606 modules, one memory interface 606 per pair of memory partition unit 420 modules, where each pair of memory partition unit 420 modules is connected to a corresponding memory 402 device. For example, parallel processing unit 404 may be connected to up to Y memory 402 devices, such as high bandwidth memory stacks or graphics double-data-rate, version 5, synchronous dynamic random access memory, or other types of persistent storage.

In an embodiment, the memory interface 606 implements an HBM2 memory interface and Y equals half U. In an embodiment, the HBM2 memory stacks are located on the same physical package as the parallel processing unit 404, providing substantial power and area savings compared with conventional GDDR5 SDRAM systems. In an embodiment, each HBM2 stack includes four memory dies and Y equals 4, with HBM2 stack including two 128-bit channels per die for a total of 8 channels and a data bus width of 1024 bits.

In an embodiment, the memory 402 supports Single-Error Correcting Double-Error Detecting (SECDED) Error Correction Code (ECC) to protect data. ECC provides higher reliability for compute applications that are sensitive to data corruption. Reliability is especially important in large-scale cluster computing environments where parallel processing unit 404 modules process very large datasets and/or run applications for extended periods.

In an embodiment, the parallel processing unit 404 implements a multi-level memory hierarchy. In an embodiment, the memory partition unit 420 supports a unified memory to provide a single unified virtual address space for CPU and parallel processing unit 404 memory, enabling data sharing between virtual memory systems. In an embodiment the frequency of accesses by a parallel processing unit 404 to memory located on other processors is traced to ensure that memory pages are moved to the physical memory of the parallel processing unit 404 that is accessing the pages more frequently. In an embodiment, the NVLink 422 supports address translation services allowing the parallel processing unit 404 to directly access a CPU's page tables and providing full access to CPU memory by the parallel processing unit 404.

In an embodiment, copy engines transfer data between multiple parallel processing unit 404 modules or between parallel processing unit 404 modules and CPUs. The copy engines can generate page faults for addresses that are not mapped into the page tables. The memory partition unit 420 can then service the page faults, mapping the addresses into the page table, after which the copy engine can perform the transfer. In a conventional system, memory is pinned (e.g., non-pageable) for multiple copy engine operations between multiple processors, substantially reducing the available memory. With hardware page faulting, addresses can be passed to the copy engines without worrying if the memory pages are resident, and the copy process is transparent.

Data from the memory 402 or other system memory may be fetched by the memory partition unit 420 and stored in the level two cache 604, which is located on-chip and is shared between the various general processing cluster 418 modules. As shown, each memory partition unit 420 includes a portion of the level two cache 604 associated with a corresponding memory 402 device. Lower level caches may then be implemented in various units within the general processing cluster 418 modules. For example, each of the streaming multiprocessor 514 modules may implement an L1 cache. The L1 cache is private memory that is dedicated to a particular streaming multiprocessor 514. Data from the level two cache 604 may be fetched and stored in each of the L1 caches for processing in the functional units of the streaming multiprocessor 514 modules. The level two cache 604 is coupled to the memory interface 606 and the crossbar 416.

The raster operations unit 602 performs graphics raster operations related to pixel color, such as color compression, pixel blending, and the like. The raster operations unit 602 also implements depth testing in conjunction with the raster engine 506, receiving a depth for a sample location associated with a pixel fragment from the culling engine of the raster engine 506. The depth is tested against a corresponding depth in a depth buffer for a sample location associated with the fragment. If the fragment passes the depth test for the sample location, then the raster operations unit 602 updates the depth buffer and transmits a result of the depth test to the raster engine 506. It will be appreciated that the number of partition memory partition unit 420 modules may be different than the number of general processing cluster 418 modules and, therefore, each raster operations unit 602 may be coupled to each of the general processing cluster 418 modules. The raster operations unit 602 tracks packets received from the different general processing cluster 418 modules and determines which general processing cluster 1 that a result generated by the raster operations unit 602 is routed to through the crossbar 416. Although the raster operations unit 602 is included within the memory partition unit 420 in FIG. 6, in other embodiment, the raster operations unit 602 may be outside of the memory partition unit 420. For example, the raster operations unit 602 may reside in the general processing cluster 418 or another unit.

FIG. 7 illustrates the streaming multiprocessor 514 of FIG. 5, in accordance with an embodiment. As shown in FIG. 7, the streaming multiprocessor 514 includes an instruction cache 702, one or more scheduler unit 704 modules (e.g., such as scheduler unit 410), a register file 706, one or more processing core 708 modules, one or more special function unit 710 modules, one or more load/store unit 712 modules, an interconnect network 714, and a shared memory/L1 cache 716.

As described above, the work distribution unit 412 dispatches tasks for execution on the general processing cluster 418 modules of the parallel processing unit 404. The tasks are allocated to a particular data processing cluster 512 within a general processing cluster 418 and, if the task is associated with a shader program, the task may be allocated to a streaming multiprocessor 514. The scheduler unit 410 receives the tasks from the work distribution unit 412 and manages instruction scheduling for one or more thread blocks assigned to the streaming multiprocessor 514. The scheduler unit 704 schedules thread blocks for execution as warps of parallel threads, where each thread block is allocated at least one warp. In an embodiment, each warp executes 32 threads. The scheduler unit 704 may manage a plurality of different thread blocks, allocating the warps to the different thread blocks and then dispatching instructions from the plurality of different cooperative groups to the various functional units (e.g., core 708 modules, special function unit 710 modules, and load/store unit 712 modules) during each clock cycle.

Cooperative Groups is a programming model for organizing groups of communicating threads that allows developers to express the granularity at which threads are communicating, enabling the expression of richer, more efficient parallel decompositions. Cooperative launch APIs support synchronization amongst thread blocks for the execution of parallel algorithms. Conventional programming models provide a single, simple construct for synchronizing cooperating threads: a barrier across all threads of a thread block (e.g., the syncthreads() function). However, programmers would often like to define groups of threads at smaller than thread block granularities and synchronize within the defined groups to enable greater performance, design flexibility, and software reuse in the form of collective group-wide function interfaces.

Cooperative Groups enables programmers to define groups of threads explicitly at sub-block (e.g., as small as a single thread) and multi-block granularities, and to perform collective operations such as synchronization on the threads in a cooperative group. The programming model supports clean composition across software boundaries, so that libraries and utility functions can synchronize safely within their local context without having to make assumptions about convergence. Cooperative Groups primitives enable new patterns of cooperative parallelism, including producer-consumer parallelism, opportunistic parallelism, and global synchronization across an entire grid of thread blocks.

A dispatch 718 unit is configured within the scheduler unit 704 to transmit instructions to one or more of the functional units. In one embodiment, the scheduler unit 704 includes two dispatch 718 units that enable two different instructions from the same warp to be dispatched during each clock cycle. In alternative embodiments, each scheduler unit 704 may include a single dispatch 718 unit or additional dispatch 718 units.

Each streaming multiprocessor 514 includes a register file 706 that provides a set of registers for the functional units of the streaming multiprocessor 514. In an embodiment, the register file 706 is divided between each of the functional units such that each functional unit is allocated a dedicated portion of the register file 706. In another embodiment, the register file 706 is divided between the different warps being executed by the streaming multiprocessor 514. The register file 706 provides temporary storage for operands connected to the data paths of the functional units.

Each streaming multiprocessor 514 comprises L processing core 708 modules. In an embodiment, the streaming multiprocessor 514 includes a large number (e.g., 128, etc.) of distinct processing core 708 modules. Each core 708 may include a fully-pipelined, single-precision, double-precision, and/or mixed precision processing unit that includes a floating point arithmetic logic unit and an integer arithmetic logic unit. In an embodiment, the floating point arithmetic logic units implement the IEEE 754-2008 standard for floating point arithmetic. In an embodiment, the core 708 modules include 64 single-precision (32-bit) floating point cores, 64 integer cores, 32 double-precision (64-bit) floating point cores, and 8 tensor cores.

Tensor cores configured to perform matrix operations, and, in an embodiment, one or more tensor cores are included in the core 708 modules. In particular, the tensor cores are configured to perform deep learning matrix arithmetic, such as convolution operations for neural network training and inferencing. In an embodiment, each tensor core operates on a 4×4 matrix and performs a matrix multiply and accumulate operation D=A′B+C, where A, B, C, and D are 4×4 matrices.

In an embodiment, the matrix multiply inputs A and B are 16-bit floating point matrices, while the accumulation matrices C and D may be 16-bit floating point or 32-bit floating point matrices. Tensor Cores operate on 16-bit floating point input data with 32-bit floating point accumulation. The 16-bit floating point multiply requires 64 operations and results in a full precision product that is then accumulated using 32-bit floating point addition with the other intermediate products for a 4×4×4 matrix multiply. In practice, Tensor Cores are used to perform much larger two-dimensional or higher dimensional matrix operations, built up from these smaller elements. An API, such as CUDA 9 C++ API, exposes specialized matrix load, matrix multiply and accumulate, and matrix store operations to efficiently use Tensor Cores from a CUDA-C++ program. At the CUDA level, the warp-level interface assumes 16×16 size matrices spanning all 32 threads of the warp.

Each streaming multiprocessor 514 also comprises M special function unit 710 modules that perform special functions (e.g., attribute evaluation, reciprocal square root, and the like). In an embodiment, the special function unit 710 modules may include a tree traversal unit configured to traverse a hierarchical tree data structure. In an embodiment, the special function unit 710 modules may include texture unit configured to perform texture map filtering operations. In an embodiment, the texture units are configured to load texture maps (e.g., a 2D array of texels) from the memory 402 and sample the texture maps to produce sampled texture values for use in shader programs executed by the streaming multiprocessor 514. In an embodiment, the texture maps are stored in the shared memory/L1 cache 716. The texture units implement texture operations such as filtering operations using mip-maps (e.g., texture maps of varying levels of detail). In an embodiment, each streaming multiprocessor 514 includes two texture units.

Each streaming multiprocessor 514 also comprises N load/store unit 712 modules that implement load and store operations between the shared memory/L1 cache 716 and the register file 706. Each streaming multiprocessor 514 includes an interconnect network 714 that connects each of the functional units to the register file 706 and the load/store unit 712 to the register file 706 and shared memory/L1 cache 716. In an embodiment, the interconnect network 714 is a crossbar that can be configured to connect any of the functional units to any of the registers in the register file 706 and connect the load/store unit 712 modules to the register file 706 and memory locations in shared memory/L1 cache 716.

The shared memory/L1 cache 716 is an array of on-chip memory that allows for data storage and communication between the streaming multiprocessor 514 and the primitive engine 516 and between threads in the streaming multiprocessor 514. In an embodiment, the shared memory/L1 cache 716 comprises 128 KB of storage capacity and is in the path from the streaming multiprocessor 514 to the memory partition unit 420. The shared memory/L1 cache 716 can be used to cache reads and writes. One or more of the shared memory/L1 cache 716, level two cache 604, and memory 402 are backing stores.

Combining data cache and shared memory functionality into a single memory block provides the best overall performance for both types of memory accesses. The capacity is usable as a cache by programs that do not use shared memory. For example, if shared memory is configured to use half of the capacity, texture and load/store operations can use the remaining capacity. Integration within the shared memory/L1 cache 716 enables the shared memory/L1 cache 716 to function as a high-throughput conduit for streaming data while simultaneously providing high-bandwidth and low-latency access to frequently reused data.

When configured for general purpose parallel computation, a simpler configuration can be used compared with graphics processing. Specifically, the fixed function graphics processing units shown in FIG. 4, are bypassed, creating a much simpler programming model. In the general purpose parallel computation configuration, the work distribution unit 412 assigns and distributes blocks of threads directly to the data processing cluster 512 modules. The threads in a block execute the same program, using a unique thread ID in the calculation to ensure each thread generates unique results, using the streaming multiprocessor 514 to execute the program and perform calculations, shared memory/L1 cache 716 to communicate between threads, and the load/store unit 712 to read and write global memory through the shared memory/L1 cache 716 and the memory partition unit 420. When configured for general purpose parallel computation, the streaming multiprocessor 514 can also write commands that the scheduler unit 410 can use to launch new work on the data processing cluster 512 modules.

The parallel processing unit 404 may be included in a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, and the like. In an embodiment, the parallel processing unit 404 is embodied on a single semiconductor substrate. In another embodiment, the parallel processing unit 404 is included in a system-on-a-chip (SoC) along with one or more other devices such as additional parallel processing unit 404 modules, the memory 402, a reduced instruction set computer (RISC) CPU, a memory management unit (MMU), a digital-to-analog converter (DAC), and the like.

In an embodiment, the parallel processing unit 404 may be included on a graphics card that includes one or more memory devices. The graphics card may be configured to interface with a PCIe slot on a motherboard of a desktop computer. In yet another embodiment, the parallel processing unit 404 may be an integrated graphics processing unit (iGPU) or parallel processor included in the chipset of the motherboard.

Systems with multiple GPUs and CPUs are used in a variety of industries as developers expose and leverage more parallelism in applications such as artificial intelligence computing. High-performance GPU-accelerated systems with tens to many thousands of compute nodes are deployed in data centers, research facilities, and supercomputers to solve ever larger problems. As the number of processing devices within the high-performance systems increases, the communication and data transfer mechanisms need to scale to support the increased bandwidth.

FIG. 8 is a conceptual diagram of a processing system implemented using the parallel processing unit 404 of FIG. 4, in accordance with an embodiment. The processing system includes a central processing unit 802, a switch 804, and multiple parallel processing unit 404 modules each and respective memory 402 modules. The switch 804 is depicted with dashed lines, indicating that it is optional in some embodiments.

The NVLink 422 provides high-speed communication links between each of the parallel processing unit 404 modules. Although a particular number of NVLink 422 and interconnect 424 connections are illustrated in FIG. 8, the number of connections to each parallel processing unit 404 and the central processing unit 802 may vary. The switch 804 interfaces between the interconnect 424 and the central processing unit 802. The parallel processing unit 404 modules, memory 402 modules, and NVLink 422 connections may be situated on a single semiconductor platform to form a parallel processing module 806. In an embodiment, the switch 804 supports two or more protocols to interface between various different connections and/or links.

In another embodiment (not shown), the NVLink 422 provides one or more high-speed communication links between each of the parallel processing unit modules (parallel processing unit 404, parallel processing unit 404, parallel processing unit 404, and parallel processing unit 404) and the central processing unit 802 and the switch 804 (when present) interfaces between the interconnect 424 and each of the parallel processing unit modules. The parallel processing unit modules, memory 402 modules, and interconnect 424 may be situated on a single semiconductor platform to form a parallel processing module 806. In yet another embodiment (not shown), the interconnect 424 provides one or more communication links between each of the parallel processing unit modules and the central processing unit 802 and the switch 804 interfaces between each of the parallel processing unit modules using the NVLink 422 to provide one or more high-speed communication links between the parallel processing unit modules. In another embodiment (not shown), the NVLink 422 provides one or more high-speed communication links between the parallel processing unit modules and the central processing unit 802 through the switch 804. In yet another embodiment (not shown), the interconnect 424 provides one or more communication links between each of the parallel processing unit modules directly. One or more of the NVLink 422 high-speed communication links may be implemented as a physical NVLink interconnect or either an on-chip or on-die interconnect using the same protocol as the NVLink 422.

In the context of the present description, a single semiconductor platform may refer to a sole unitary semiconductor-based integrated circuit fabricated on a die or chip. It should be noted that the term single semiconductor platform may also refer to multi-chip modules with increased connectivity which simulate on-chip operation and make substantial improvements over utilizing a conventional bus implementation. Of course, the various circuits or devices may also be situated separately or in various combinations of semiconductor platforms per the desires of the user. Alternately, the parallel processing module 806 may be implemented as a circuit board substrate and each of the parallel processing unit modules and/or memory 402 modules may be packaged devices. In an embodiment, the central processing unit 802, switch 804, and the parallel processing module 806 are situated on a single semiconductor platform.

In an embodiment, each parallel processing unit module includes six NVLink 422 interfaces (as shown in FIG. 8, five NVLink 422 interfaces are included for each parallel processing unit module). The NVLink 422 may be operated exclusively for PPU-to-PPU communication as shown in FIG. 8, or some combination of PPU-to-PPU and PPU-to-CPU, when the central processing unit 802 also includes one or more NVLink 422 interfaces.

In an embodiment, the NVLink 422 allows direct load/store/atomic access from the central processing unit 802 to each parallel processing unit module's memory 402. In an embodiment, the NVLink 422 supports coherency operations, allowing data read from the memory 402 modules to be stored in the cache hierarchy of the central processing unit 802, reducing cache access latency for the central processing unit 802. In an embodiment, the NVLink 422 includes support for Address Translation Services (ATS), enabling the parallel processing unit module to directly access page tables within the central processing unit 802. One or more of the NVLink 422 may also be configured to operate in a low-power mode.

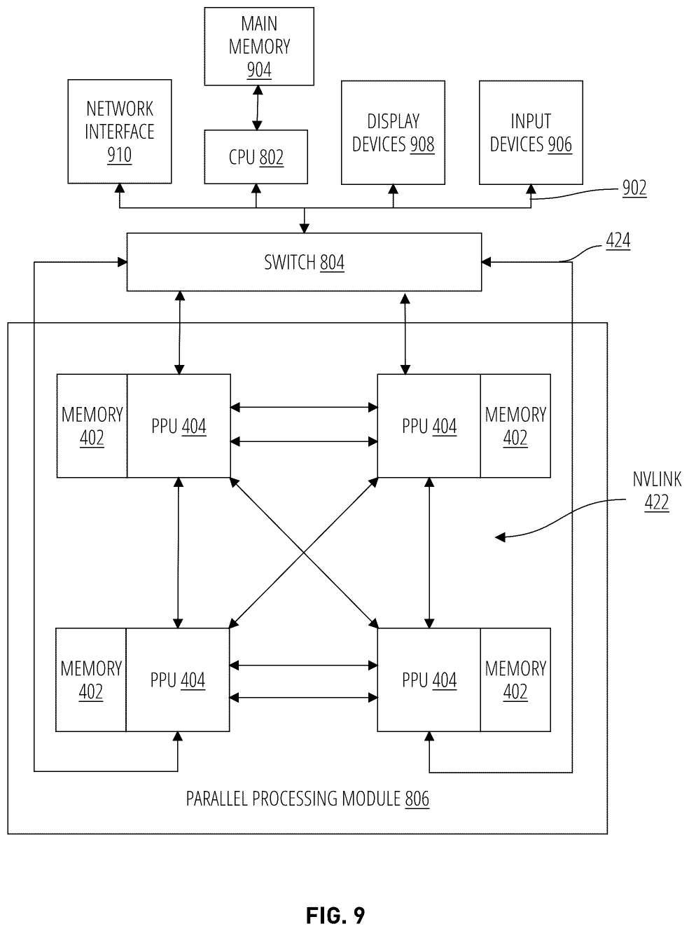

FIG. 9 depicts an exemplary processing system in which the various architecture and/or functionality of the various previous embodiments may be implemented. As shown, an exemplary processing system is provided including at least one central processing unit 802 that is connected to a communications bus 902. The communication communications bus 902 may be implemented using any suitable protocol, such as PCI (Peripheral Component Interconnect), PCI-Express, AGP (Accelerated Graphics Port), HyperTransport, or any other bus or point-to-point communication protocol(s). The exemplary processing system also includes a main memory 904. Control logic (software) and data are stored in the main memory 904 which may take the form of random access memory (RAM).

The exemplary processing system also includes input devices 906, the parallel processing module 806, and display devices 908, e.g. a conventional CRT (cathode ray tube), LCD (liquid crystal display), LED (light emitting diode), plasma display or the like. User input may be received from the input devices 906, e.g., keyboard, mouse, touchpad, microphone, and the like. Each of the foregoing modules and/or devices may even be situated on a single semiconductor platform to form the exemplary processing system. Alternately, the various modules may also be situated separately or in various combinations of semiconductor platforms per the desires of the user.

Further, the exemplary processing system may be coupled to a network (e.g., a telecommunications network, local area network (LAN), wireless network, wide area network (WAN) such as the Internet, peer-to-peer network, cable network, or the like) through a network interface 910 for communication purposes.

The exemplary processing system may also include a secondary storage (not shown). The secondary storage includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner.

Computer programs, or computer control logic algorithms, may be stored in the main memory 904 and/or the secondary storage. Such computer programs, when executed, enable the exemplary processing system to perform various functions. The main memory 904, the storage, and/or any other storage are possible examples of computer-readable media.

The architecture and/or functionality of the various previous figures may be implemented in the context of a general computer system, a circuit board system, a game console system dedicated for entertainment purposes, an application-specific system, and/or any other desired system. For example, the exemplary processing system may take the form of a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, a mobile phone device, a television, workstation, game consoles, embedded system, and/or any other type of logic.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

### LISTING OF DRAWING ELEMENTS

102 global placement
104 congestion estimation
106 congestion mitigation
202 Electronic Design Automation system
204 cell density distribution determination logic
206 component placement system
208 candidate component placement
210 density adaption logic
302 placer
304 Bayes adapter
306 post-routing optimized netlist
402 memory
404 parallel processing unit
406 I/O unit
408 front-end unit
410 scheduler unit
412 work distribution unit
414 hub
416 crossbar
418 general processing cluster
420 memory partition unit
422 NVLink
424 interconnect
502 pipeline manager
504 pre-raster operations unit
506 raster engine
508 work distribution crossbar
510 memory management unit
512 data processing cluster
514 streaming multiprocessor
516 primitive engine
518 M-pipe controller
602 raster operations unit
604 level two cache
606 memory interface
702 instruction cache
704 scheduler unit
706 register file
708 core
710 special function unit
712 load/store unit
714 interconnect network
716 shared memory/L1 cache
718 dispatch
802 central processing unit
804 switch
806 parallel processing module
902 communications bus
904 main memory
906 input devices
908 display devices
910 network interface

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device.

Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112 (f) for that claim element. Accordingly, claims in this application that do not otherwise include the “means for” [performing a function] construct should not be interpreted under 35 U.S.C § 112 (f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the disclosure as claimed. The scope of inventive subject matter is not limited to the depicted embodiments but is rather set forth in the following Claims.

What is claimed is:

1. A system comprising:
a component placement system configured to generate placements for a circuit that conform to a target cell density distribution;
a Bayes adapter configured to transform outputs of the component placement system into a modified cell density distribution; and
the system configured to apply the modified cell density distribution to the component placement system as an updated target cell density distribution.

2. The system of claim 1, further comprising:
logic configured to transform a post-routing netlist for the circuit into an initial target cell density distribution for the component placement system.

3. The system of claim 2, further comprising:
an Electronic Design Automation system configured to generate the post-routing netlist.

4. The system of claim 1, wherein the Bayes adapter is configured to generate a James-Stein cell density distribution for the component placement system.

5. The system of claim 1, wherein the component placement system is configured to converge on the updated target cell density distribution by inflating cells of the circuit during global component placement.

6. The system of claim 5, wherein the component placement system is configured to adjust an inflation factor applied to particular cells based on the timing criticality of the particular cells.

7. The system of claim 5, wherein the component placement system is configured to apply a cell inflation factor
$${r}_{i} = \frac{1}{{t}_{i}}$$
where tᵢ represents a target density of cell i.

8. The system of claim 1, wherein the component placement system is configured to output a set of top Pareto point global placements with inflation applied to the target cell density distribution.

9. The system of claim 1, wherein the Bayes adapter is configured to avoid the generation of cell density distributions that are not achievable by the component placement system.

10. The system of claim 1, wherein the component placement system is configured to minimize a Hellinger distance determined from a plurality of cell density distributions.

11. The system of claim 1, wherein the component placement system is configured to shift the target cell density distribution within a set range.

12. A process for placing circuit components, the process comprising:
generating a placement for a circuit that conforms to a target cell density distribution;
processing the placement through a Bayes adapter to transform the placement into a cell density distribution; and
applying the cell density distribution to a component placement system as a target cell density distribution.

13. The process of claim 12, further comprising:
transforming a post-routing netlist for a circuit into an initial target cell density distribution for the component placement system.

14. The process of claim 13, further comprising:
operating an Electronic Design Automation system to generate the post-routing netlist.

15. The process of claim 12, further comprising:
operating the Bayes adapter to generate a James-Stein cell density distribution for the component placement system.

16. The process of claim 12, wherein the component placement system converges on the target cell density distribution by inflating cells of the circuit during global component placement.

17. The process of claim 16, wherein the component placement system applies a cell inflation factor
$${r}_{i} = \frac{1}{{t}_{i}}$$
where tᵢ represents a target density of cell i.

18. The process of claim 12, wherein the Bayes adapter avoids the generation of cell density distributions that are not achievable by the component placement system.

19. A system comprising:
at least one graphics processing unit; and
logic that configures the graphics processing unit to:
generate a placement for a circuit that conforms to a target cell density distribution;
process the placement through a Bayes adapter to transform the placement into a cell density distribution; and
apply the cell density distribution to a component placement system as a target cell density distribution.

20. The system of claim 19, wherein the component placement system is configured to adjust an inflation factor applied to particular cells of the circuit based on the timing criticality of the particular cells.
